(19) United States
(12) Patent Application Publication
(10) Pub. No.: US 2018/0374604 A1
(43) Pub. Date: Dec. 27, 2018

(54) PORTABLE DATA CABLE

(71) Applicant: KEDAO TECHNOLOGIES (SHENZHEN) CO., LTD., Shenzhen (CN)

(72) Inventors: Xiangdong YANG, Shenzhen (CN); Ji HUANG, Shenzhen (CN)

(21) Appl. No.: 15/896,229

(22) Filed: Feb. 14, 2018

(30) Foreign Application Priority Data
Jun. 26, 2017 (CN) 201710496568.0

(51) Int. Cl. H01B 7/00; H01B 7/04; H01B 7/40; H01B 11/00; H05K 1/02; H05K 1/11

(52) U.S. Cl. CPC H01B 7/009; H01B 7/04; H01B 7/40; H05K 1/11; H05K 1/0281; H05K 1/0296; H01B 11/002

(57) ABSTRACT

The present invention relates to a portable data cable. The portable data cable includes a first terminal and a second terminal that are disposed on two ends of the portable data cable, and a body portion connected between the first terminal and the second terminal, wherein the first terminal includes a first interface, a first protruding portion, a first recess portion, and a first receiving portion, all of which are sequentially disposed along a connection direction; the second terminal includes a second interface, a second protruding portion, a second recess portion, and a second receiving portion, all of which are sequentially disposed along the connection direction, wherein the first recess portion is configured to facilitate insertion of the second interface into the first receiving portion, and the second recess portion is configured to facilitate insertion of the first interface into the second receiving portion, and wherein the first terminal and the second terminal are configured to be capable of being connected by using mortise-and-tenon structures and making the portable data cable become a closed loop, whereby the first interface is accommodated in the second receiving portion, and the second interface is accommodated in the first receiving portion. The portable data cable according to the present invention is convenient to connect and carry. People will have a good experience from using the portable cable.

### BACKGROUND OF THE INVENTION

### 1. Field of the Invention

The present invention relates to the technical field of electronic data cables, and particularly to a portable data cable, especially a wearable data cable suitable to be worn on a body part.

### 2. Description of the Related Art

Data cables are now one of the products that are most widely used in electronic devices. Functions of data cables include data transmission 1o between one electronic device and another electronic device, power charging, and so on. Most of the existing data cables are line-shaped. The shapes of the lines are irregular and the designs of the lines have no special features. Consequently, it is not only inconvenient to carry this type of data cable but also easy for one to forget to carry this type of data cable when he or she goes out, causing troubles in using this type of data cable.

### SUMMARY OF THE INVENTION

An objective of the present invention is to provide a portable data cable, which can be carried on a body part and create a good user experience.

The present invention is implemented using the following technical solution: a portable data cable, including a first terminal and a second terminal, all of which are disposed on two ends of the portable data cable, and a body portion connected between the first terminal and the second terminal, where the first terminal includes a first interface, a first protruding portion, a first recess portion, and a first receiving portion, all of which are sequentially disposed along a connection direction; the second terminal includes a second interface, a second protruding portion, a second recess portion, and a second receiving portion, all of which are sequentially disposed along the connection direction, wherein the first recess portion is configured to facilitate insertion of the second interface into the first receiving portion, and the second recess portion is configured to facilitate insertion of the first interface into the second receiving portion, and wherein the first terminal and the second terminal are configured to be capable of being connected by using mortise-and-tenon structures and making the portable data cable become a closed loop, whereby the first interface is accommodated in the second receiving portion, and the second interface is accommodated in the first receiving portion. In the present invention, the receiving portions are used together with the interfaces. For example, the first receiving portion is used together with the second interface, and the second receiving portion is used together with the first interface. The functions of the receiving portions include providing a receiving place for receiving the interfaces, and constraining interfaces, so that when the two terminals (the first and second terminals) are in a connected state or in a closed-loop state, the interfaces do not easily detach from the receiving portions, thereby remaining in the connected or closed-loop state. Therefore, the shapes, sizes, thicknesses, matching states, and the like of the receiving portions and the interface should all meet the foregoing objective. Because this is common general knowledge to a person skilled in the art, details are not described herein again.

As a further improvement of the foregoing technical solution, when the first terminal is connected to the second terminal, the first protruding portion and the second recess portion match each other in a mortise-and-tenon manner in a first matching direction, and the second protruding portion and the first recess portion match each other in a mortise-and-tenon manner in a second matching direction opposite the first matching direction.

In the present invention, a “matching direction” is a direction in which a protruding portion enters a recess portion. Assuming that the direction in which the protruding portion enters downwards from the top of the recess portion is the first matching direction, a direction in which the protruding portion enters upwards from the bottom of the recess portion is the second matching direction. Assuming that a direction in which the protruding portion enters rightwards from the left of the recess portion is the first matching direction, a direction in which the protruding portion enters leftwards from the right of the recess portion is the second matching direction, and vice versa. For example, assuming that a direction in which the protruding portion enters downwards from the top of the recess portion is the second matching direction, a direction in which the protruding portion enters downwards from the top of the recess portion is the first matching direction.

As a further improvement of the foregoing technical solution, the first recess portion and the second recess portion are both through holes that extend vertically along a thickness direction.

As a further improvement of the foregoing technical solution, the first receiving portion and the second receiving portion are open towards an inner side along the thickness direction and are closed towards an outer side.

As a further improvement of the foregoing technical solution, when the first terminal is connected to the second terminal, the first protruding portion protrudes upwards along the thickness direction into the second recess portion and the second protruding portion protrudes downwards along the thickness direction into the first recess portion.

As a further improvement of the foregoing technical solution, a first transition portion is disposed between the first protruding portion and the first recess portion, a second transition portion is disposed between the second protruding portion and the second recess portion, and when the first terminal is connected to the second terminal, the first transition portion vertically overlaps with the second transition portion.

As a further improvement of the foregoing technical solution, when the first terminal is connected to the second terminal, the first protruding portion protrudes leftwards along a width direction into the second recess portion and the second protruding portion protrudes rightwards along the width direction into the first recess portion.

As a further improvement of the foregoing technical solution, the first receiving portion and the second receiving portion are closed towards both an inner side and an outer side along the thickness direction.

As a further improvement of the foregoing technical solution, the first receiving portion and the second receiving portion are closed towards both an inner side and an outer side along the thickness direction; when the first terminal is connected to the second terminal, the first recess portion is a bottom-containing groove recessed downwards along the thickness direction, the second recess portion is a bottom-containing groove recessed upwards along the thickness direction, the first protruding portion protrudes upwards along the thickness direction into the second recess portion, and the second protruding portion protrudes downwards along the thickness direction into the first recess portion.

As a further improvement of the foregoing technical solution, a first transition inclined surface is disposed between the first protruding portion and the first recess portion, a second transition inclined surface is disposed between the second protruding portion and the second recess portion, and when the first terminal is connected to the second terminal, the first transition inclined surface matches the second transition inclined surface.

As a further improvement of the foregoing technical solution, a flexible printed circuit board implementing electrical connection is disposed in the first terminal and/or the second terminal, the flexible printed circuit board including a frame body matching the shape of the corresponding first terminal or second terminal and an electrical contact electrically connected to the frame body.

As a further improvement of the foregoing technical solution, a flexible printed circuit board implementing electrical connection is disposed in each of the first terminal and the second terminal, and a connection medium located between the flexible printed circuit board on the first terminal and the flexible printed circuit board on the second terminal is a flat band-shaped conductive medium. As another further improvement of the foregoing technical solution, a reinforcing sheet having a shape corresponding to the shape of the frame body is attached on the frame body. The reinforcing sheet may be, for example, a stainless steel sheet having a relatively large mechanical strength. The reinforcing sheet may be an integral bar-shaped sheet in a closed loop or that of multiple split-type bar-shaped sheets.

It should be noted that, in the present invention, an “interface” is a port that is disposed on one electronic device and is configured to perform electric power transmission and exchange data information between the electronic device and another independent electronic device. The “body portion” is a portion, other than the first terminal and the second terminal, of the portable data cable. The “mortise-and-tenon” manner is a connection manner in which concave and convex parts are combined on two components. The convex part is referred to as a mortise, and the concave portion is referred to as a tenon.

It should be noted that, in the present invention, the “inner side” is a side of the portable data cable in a normal use state that is closer to a supporting object in the thickness direction, and a side farther away from the supporting object is referred to as the “outer side”. For example, when the data cable is worn on a wrist, the inner side is a side closer to the skin in the thickness direction, and the outer side is a side farther away from the skin in the thickness direction.

It should be noted that, in the present invention, “flat” is used to describe a tabular shape in which the thickness of an object is far less than the length or width of the object. For example, the thickness is approximately one fifth to one twentieth of the length or width, or is less than one twentieth of the length or width. It should also be noted that, in the present invention, the flexible printed circuit (of which the abbreviation is FPCB or FPC) is a flexible printed circuit board that is manufactured using polyimide, a polyester film, or the like as a substrate and that has high reliability, and the flexible printed circuit board has the features of light weight, slimness, and good bendability.

It should further be noted that, in the present invention, an “electrical contact” is an intermediate medium configured to connect two objects.

The benefits of the present invention are as follows. According to the portable data cable of the present invention, the first recess portion is configured to facilitate insertion of the second interface into the first receiving portion, the second recess portion is configured to facilitate insertion of the first interface into the second receiving portion, and the first terminal and the second terminal are configured to be capable of being connected by using mortise-and-tenon structures and making the portable data cable become a closed loop, and in this case, the first interface is accommodated in the second receiving portion and the second interface is accommodated in the first receiving portion so that the portable data cable is convenient to carry and use. The first terminal is connected to the second terminal by using the mortise-and-tenon structures to form the closed loop so that the data cable after connection is compact on the whole. Because the two end portions fit into each other using the mortise-and-tenon structures and are not “superposed” on each other in the thickness direction, the two terminals have relatively small thicknesses. In addition, the data cable of the present invention does not easily detach when worn on a user, but the two terminals can be easily opened and disconnected.

### BRIEF DESCRIPTION OF THE DRAWINGS

The present invention is described in detail below with reference to the appended drawings, wherein

FIG. 1a is a three-dimensional schematic diagram of a portable data cable according to a first embodiment of the present invention worn on a user;

FIG. 1b is another three-dimensional schematic diagram of the portable data cable according to the first embodiment of the present invention in the worn state;

FIG. 1c is a schematic cross-sectional view of the middle part of the portable data cable according to the first embodiment of the present invention in the worn state:

FIG. 1d is a schematic top view of the portable data cable in an expanded state according to the first embodiment of the present invention;

FIG. 1e is a schematic bottom view of the portable data cable according to the first embodiment of the present invention in the expanded state:

FIG. 1f is a diagram of the first step of an exemplary process (connection process) of wearing the portable data cable according to the first embodiment of the present invention;

FIG. 1g is a diagram of the second step of the exemplary wearing process (connection process) of the portable data cable according to the first embodiment of the present invention:

FIG. 1h is a diagram of the third step of the exemplary wearing process (connection process) of the portable data cable according to the first embodiment of the present invention;

FIG. 1i is another diagram of the third step of the exemplary wearing process (connection process) of the portable data cable according to the first embodiment of the present invention:

FIG. 1j is a diagram of the fourth step of the exemplary wearing process (connection process) of the portable data cable according to the first embodiment of the present invention;

FIG. 1k is a diagram of the shape of a flexible printed circuit board that is configured to implement electrical connection and that is disposed in a first terminal and/or a second terminal of the portable data cable according to the first embodiment of the present invention:

FIG. 1l is a diagram of the shape of a reinforcing sheet attached on a frame body of the flexible printed circuit board that is configured to implement electrical connection and that is disposed in the first terminal and/or the second terminal of the portable data cable according to the first embodiment of the present invention;

FIG. 1m is an enlarged view of part A in FIG. 1l;

FIG. 2a is a three-dimensional schematic diagram of a portable data cable according to a second embodiment of the present invention:

FIG. 2b is a partial schematic cross-sectional view of a part of the portable data cable according to the second embodiment of the present invention, and is used to display the shape of a flexible printed circuit board that is configured to implement electrical connection and that is disposed in a first terminal and/or a second terminal, and particularly is used to display the shape of a connection medium located between the flexible printed circuit board on the first terminal and the flexible printed circuit board on the second terminal;

FIG. 3a is a three-dimensional schematic diagram of a portable data cable according to a third embodiment of the present invention;

FIG. 3b is another schematic diagram of the portable data cable according to the third embodiment of the present invention:

FIG. 4a is a three-dimensional schematic diagram of a portable data cable according to a fourth embodiment of the present invention:

FIG. 4b is a schematic cross-sectional view of the middle part of the portable data cable according to the fourth embodiment of the present invention; and

FIG. 5 is a schematic cross-sectional view of the middle part of a portable data cable according to a fifth embodiment of the present invention.

### PREFERRED EMBODIMENT OF THE PRESENT INVENTION

The following provides a clear and complete description of the technical solutions in the embodiments of the present invention with reference to the accompanying drawings in the embodiments of the present invention. Obviously, the described embodiments are only some but not all of the embodiments of the present invention. In general, the components described in the embodiments of the present invention and shown in the accompanying drawings may be arranged and designed in different configurations. Therefore, the following detailed description of the embodiments of the present invention, as presented in the accompanying drawings, is not intended to limit the protection scope of the present invention, but is merely representative of selected embodiments of the present invention. Based on the embodiments of the present invention, all other embodiments that can be obtained by a person of skilled in the art without creative efforts fall within the protection scope of the present invention.

In the description of the embodiments of the present invention, it should be understood that orientation or position relationships indicated by terms such as “length”, “width”, “thickness,” “on”, “below”, “front”, “back”, left”, “right”, “vertical”, “horizontal”, “top”, “bottom”, “inside”, “outside”, “clockwise”, and “anti-clockwise” are based on orientation or position relationships shown in the accompanying drawings, and are used merely for the purpose of describing the embodiments of the present invention and simplifying the description, rather than for indicating or implying that the mentioned apparatus or element must have a specific orientation and must be constructed and operated in the specific orientation, and therefore such terms should not be construed as limitations to the embodiments of the present invention.

In the description of the embodiments of the present invention, it should be understood that the term “connection direction” refers to a direction formed by a first terminal and a second terminal when the first terminal is connected to the second terminal, wherein the direction is consistent with the length direction of the first terminal and the second terminal. The term “thickness direction” refers to a direction perpendicular to upper and lower opposite surfaces of the first terminal and the second terminal and consistent with the height direction of the first terminal and the second terminal. The term “width direction” refers to the direction of the width of the first terminal and the second terminal. In the accompanying drawings, the reference symbol of the “connection direction” is X, the reference symbol of the “thickness direction” is Y, and the reference symbol of the “width direction” is Z. Any two of the connection direction X, the thickness direction Y, and the width direction Z are perpendicular to each other.

### First Embodiment

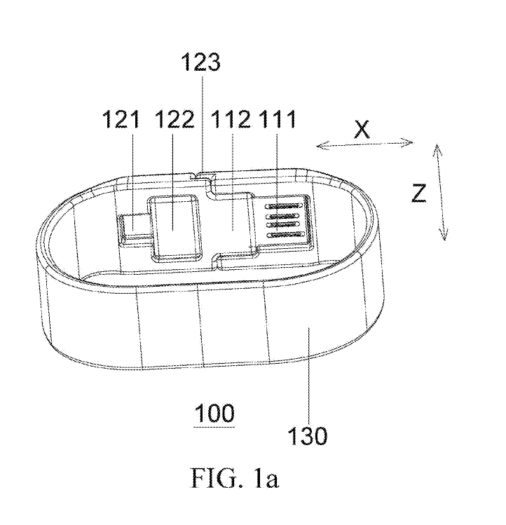

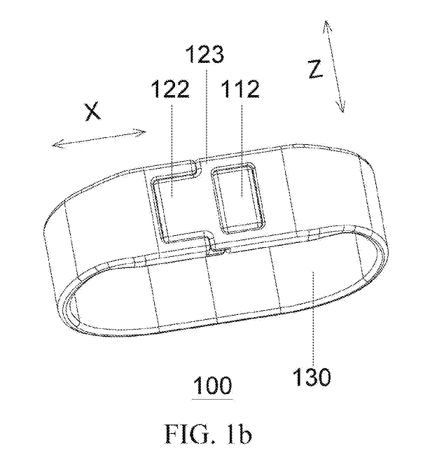

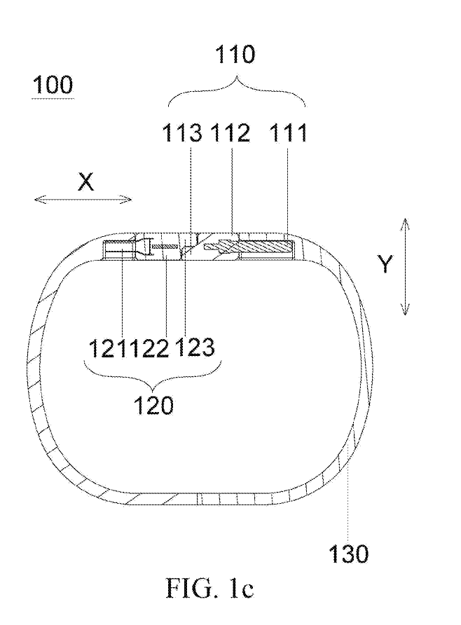

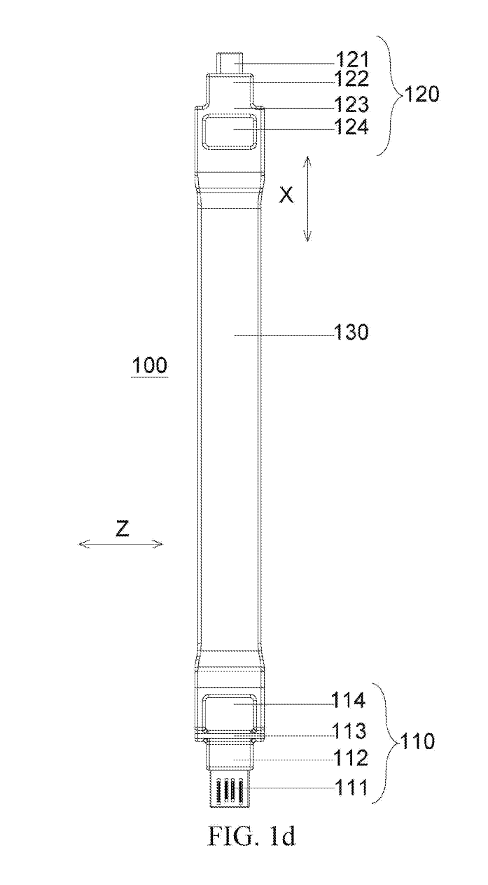

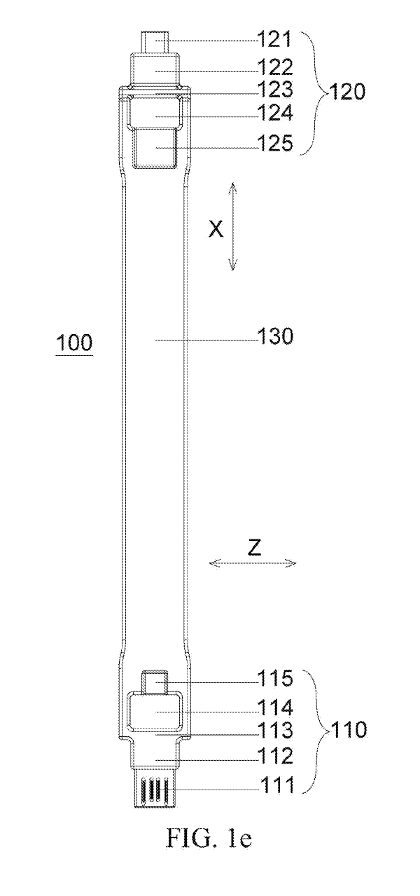

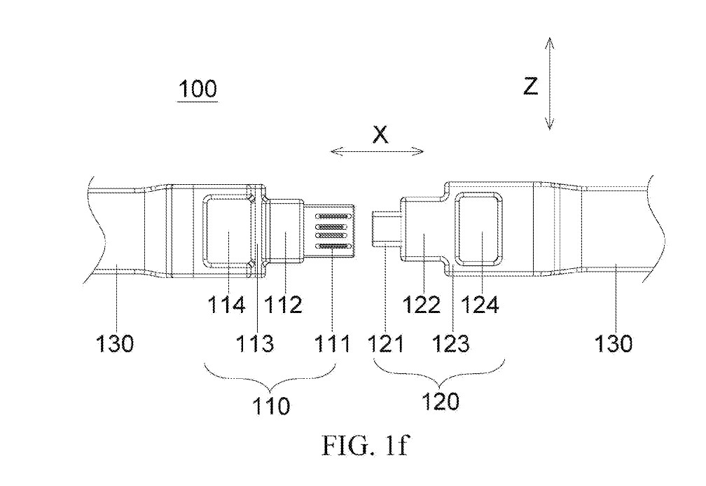

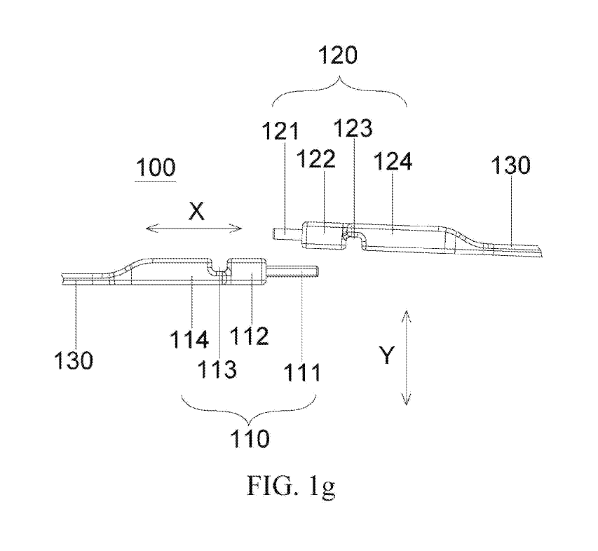

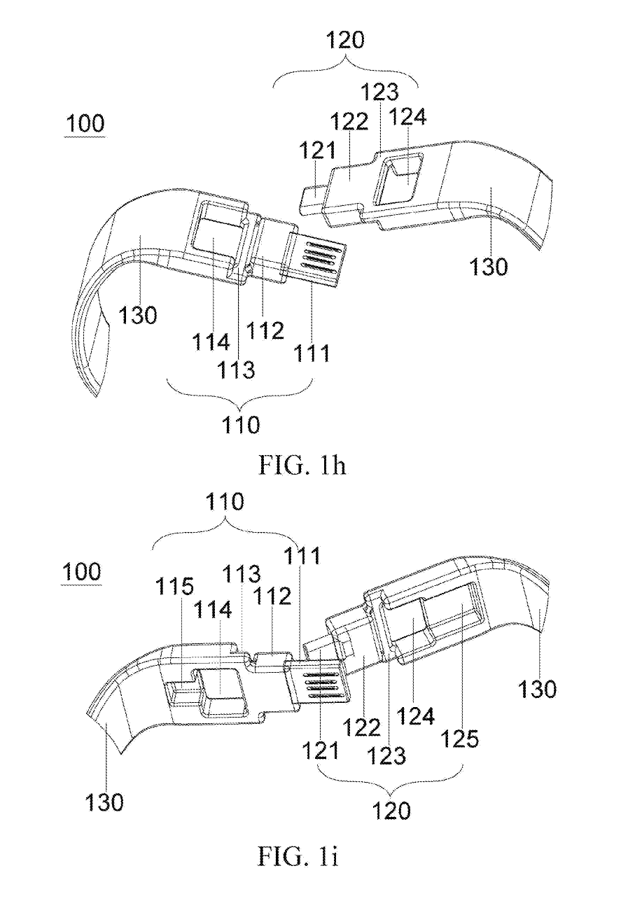

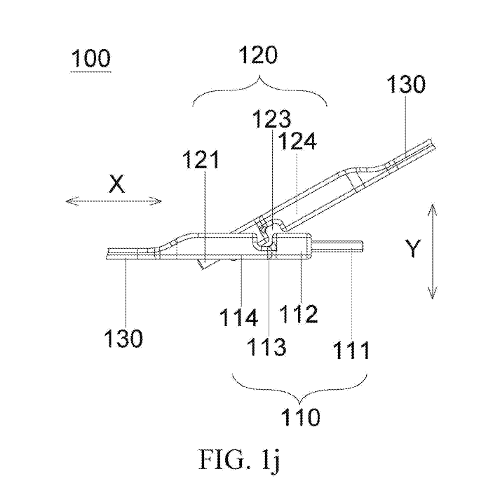

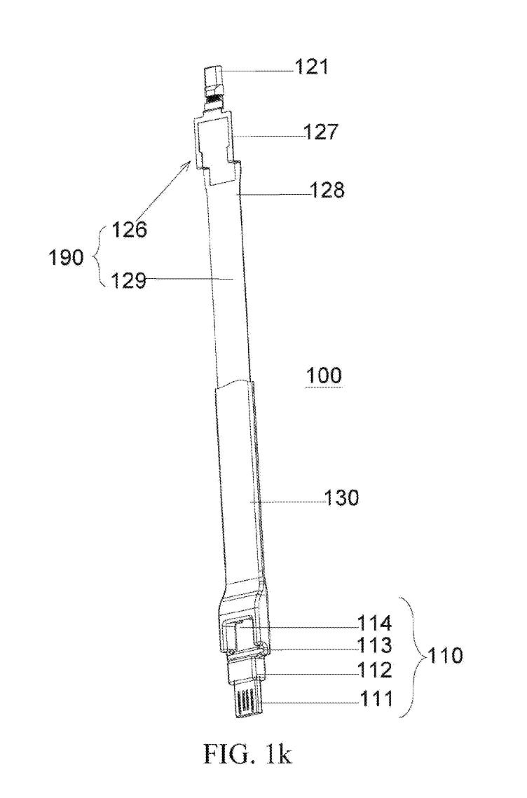

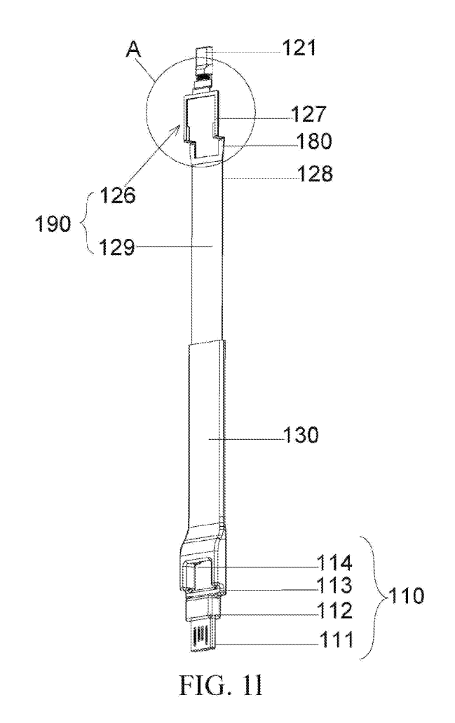

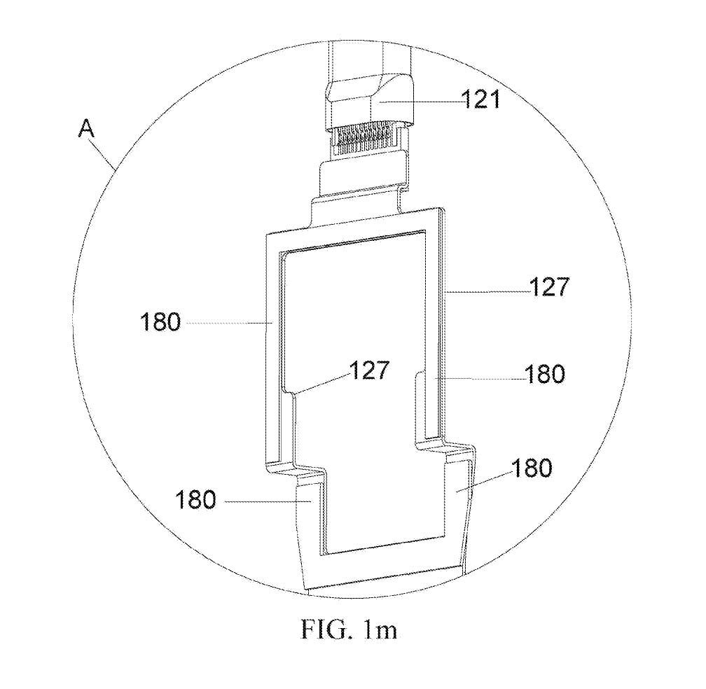

First, a portable data cable of the first embodiment of the present invention is described with reference to FIG. 1a through FIG. 1m.

As shown in FIG. 1a through FIG. 1l, a portable data cable 100 of this embodiment includes a first terminal 110, a second terminal 120, and a body portion 130 connected between the first terminal 110 and the second terminal 120. As shown in FIG. 1d and FIG. 1e, the first terminal 110 and the second terminal 120 are respectively located on two ends of the portable data cable 100.

In the first embodiment, the portable data cable 100 is designed as a bracelet that can be worn on a wrist, and has both a practical function of a charging data cable and a decorative function.

The first terminal 110 includes a first interface 111, a first protruding portion 112, a first recess portion 114, and a first receiving portion 115, all of which are sequentially disposed along a connection direction X.

The second terminal 120 includes a second interface 121, a second protruding portion 122, a second recess portion 124, and a second receiving portion 125, all of which are sequentially disposed along the connection direction X.

When the first terminal 110 is connected to the second terminal 120, the portable data cable 100 forms a closed loop that can be worn as a bracelet. When the first terminal 110 is separated from the second terminal 120, the portable data cable 100 forms a line for connection between two electronic devices (such as mobile phones, tablet computers, charging points, computers, and other electronic digital products or accessories), so as to perform data signal and electric power transmission.

A conductive transmission medium 190 that electrically connects the first interface 111 to the interface 121 is built in the portable data cable 100. The conductive transmission medium 190 is embedded in the first terminal 110, the second terminal 120, and the body portion 130 so that the data cable provides smooth electrical connection.

As shown in FIG. 1a through FIG. 1j, the first terminal 110 includes the first interface 111, the first protruding portion 112, the first recess portion 114, and the first receiving portion 115, all of which are sequentially disposed along the connection direction X. The first interface 111 is located on a free end of the first terminal 110.

A person of ordinary skill in the art should know that the first interface 111 may be a USB C type interface, a USB A type interface, a USB B type interface (Micro/Mini), a Lightning interface of Apple Inc., a combination of the foregoing interfaces (such as a combination of a Micro USB B type interface and a Lighting interface, a USB A type interface and a Micro USB B type interface, or a USB A type interface and a USB C type interface), or the like. The first interface 111 may be a female connector or a male connector, and its main function is to connect electronic devices (such as mobile phones, tablet computers, charging points, computers, and other electronic digital products or accessories), so as to perform data signal and electric power transmission.

As shown in FIG. 1a through FIG. 1j, the second terminal 120 includes the second interface 121, the second protruding portion 122, the second recess portion 124, and the second receiving portion 125, all of which are sequentially disposed along the connection direction X. The second interface 121 is located on a free end of the second terminal 120.

A person of ordinary skill in the art should know that the second interface 121 may also be a USB C type interface, a USB A type interface, a USB B type interface (Micro/Mini), a Lightning interface of Apple Inc., a combination of the foregoing interfaces (such as a combination of a Micro USB B type interface and the Lightning interface, a USB A type interface and a Micro USB B type interface, or a USB A type interface and a USB C type interface), or the like. The second interface 121 may be a female connector or a male connector, and its main function is to connect electronic devices (such as mobile phones, tablet computers, charging points, computers, and other electronic digital products or accessories), so as to perform data signal and electric power transmission.

In this embodiment, the first terminal 110 and the second terminal 120 can be connected by using mortise-and-tenon structures and making the portable data cable become a closed loop, as shown in FIG. 1a through FIG. 1c. In this case, the first interface 111 is accommodated in the second receiving portion 125, and the second interface 121 is accommodated in the first receiving portion 115.

The term “mortise-and-tenon structures” refers to pairs of mortises and tenons, wherein a mortise and a tenon in each pair match to each other in an opposite direction. That is, when the first terminal 110 is connected to the second terminal 120, the first protruding portion 112 and the second recess portion 124 match each other in a mortise-and-tenon manner in a first matching direction, and the second protruding portion 122 and the first recess portion 114 match each other in a mortise-and-tenon manner in a second matching direction opposite the first matching direction. The “first matching direction” is the direction in which the first protruding portion 112 enters the second recess portion 124. The “second matching direction” is the direction in which the second protruding portion 122 enters the first recess portion 114.

As shown in FIG. 1c, FIG. 1g, and FIG. 1j, in the first embodiment, the first matching direction is upwards along a thickness direction Y, the second matching direction is downwards along the thickness direction Y, and the second matching direction is opposite the first matching direction.

As shown in FIG. 1d, FIG. 1e, and FIG. 1f, in the first embodiment, the first recess portion 114 and the second recess portion 124 are both through holes that are vertically through along the thickness direction Y.

The first recess portion 114 is configured to facilitate accommodation of the second connecting part 121 into the first receiving portion 115, and the second recess portion 124 is configured to facilitate accommodation of the first connecting part 111 into the second receiving portion 125. In other words, when the first terminal 110 is connected to the second terminal 120, the second connecting part 121 is inserted into the first receiving portion 115 through the first recess portion 114, and the first connecting part 111 is inserted into the second receiving portion 125 through the second recess portion 124. The first recess portion 114 is in communication with the first receiving portion 115. The second recess portion 124 is in communication with the second receiving portion 125. The first recess portion 114 and the second recess portion 124 not only have the function of plugging guiding channels but also are used as mortises for receiving the second protruding portion 122 and the first protruding portion 112. Although the first recess portion 114 and the second recess portion 124 in this embodiment are both through holes that extend vertically along the thickness direction Y, the present invention is not limited thereto as long as the first recess portion 114 and the second recess portion 124 can facilitate passing of the first connecting part and the second connecting part and can engage with the second protruding portion 122 and the first protruding portion 112. As stated in the third to fifth embodiments, the first recess portion and the second recess portion may have other shapes.

As shown in FIG. 1a through FIG. 1j, the first receiving portion 115 is adapted to accommodate the second connecting part 121, and the second receiving portion 125 is adapted to accommodate the first connecting part 111. In the first embodiment, the first receiving portion 115 and the second receiving portion 125 are open towards an inner side along the thickness direction Y and are closed towards an outer side. When the first terminal 110 is connected to the second terminal 120, the first connecting part 111 is close-fitted into the second receiving portion 125, and the second connecting part 121 is close-fitted into the first receiving portion 115. As shown in FIG. 1i, the outer side of the first receiving portion 115 is closed and the inner side of the first receiving portion 115 is open to facilitate convenient downward detachment of the second connecting part 121. As shown in FIG. 1i, the outer side of the second receiving portion 215 is closed and the inner side of the second receiving portion 215 is open to facilitate convenient downward detachment of the first connecting part 111.

As shown in FIG. 1a through FIG. 1j, in the first embodiment, a first transition portion 113 is disposed between the first protruding portion 112 and the first recess portion 114, a second transition portion 123 is disposed between the second protruding portion 122 and the second recess portion 124, and when the first terminal 110 is connected to the second terminal 120, the first transition portion 113 vertically overlaps with the second transition portion 123. The first transition portion 113 and the second transition portion 123 can enhance the strength of the first terminal 110 and the second terminal 120 and can extend the life of the portable data cable.

A conductive transmission medium 190 disposed in the portable data cable 100 may be an electronic cable, a flexible printed circuit board (FPC), a combination of an electronic cable and a flexible printed circuit board, or the like, and the conductive transmission medium 190 may be in any form as long as it can implement frictionless electrical connection.

The conductive transmission medium 190 is mainly used for electrically connecting the first terminal 110 to the second terminal 120 so as to implement the function of transmitting data signals and electric power. In the specific embodiment, for example, conductive parts (an end of an electronic cable or a copper foil solder pad of a flexible printed circuit board) of two terminals of a conductive transmission medium in the body portion 130 may be respectively soldered on conductive parts (pins of the first connecting part and the second connecting part) of the first terminal 110 and the second terminal 120 by a tin soldering process. When the portable data cable 100 needs to use an IC chip (for example, an identity information signal IC chip needed by a Lightning connecting part or an IC chip needed by a USB C type connecting part), the conductive transmission medium (for example, in the foregoing two forms having a flexible printed circuit board) may be further used for carrying some of the elements connected to chips of the circuit board.

When the conductive transmission medium is an electronic cable, the electronic cable is not limited to a bare core metallic wire or may be a conductive medium such as a metallic wire coated with an insulation layer or an enameled wire. The body portion may be a covering portion of the electronic cable or may be manufactured by plastic injection and/or weaving.

When the conductive transmission medium is a flexible printed circuit board, the flexible printed circuit board (with or without a reinforcing sheet) may alternatively be a soft and hard combined circuit board formed by combining a rigid printed circuit board (PCB) and a flexible printed circuit board. The rigid printed circuit board and the flexible printed circuit board may be combined, for example, by soldering a solder pad of the flexible printed circuit board on a solder pad of the rigid printed circuit board by way of tin soldering, or by first connecting the flexible printed circuit board to the rigid printed circuit board using an adhesive (such as a thermosetting adhesive) and then performing plating using a through hole for electrical connection. Because this is common general knowledge to a person skilled in the art, details are not described herein again.

When the conductive transmission medium is a combination of an electronic cable and a flexible printed circuit board, in general, the flexible printed circuit board is mainly disposed in the first terminal and the second terminal and the electronic cable is mainly disposed in the body portion. Similarly, in this case, the flexible printed circuit board (with or without a reinforcing sheet) may alternatively be a soft and hard combined circuit board formed by combining a rigid printed circuit board (PCB) and a flexible printed circuit board.

The reinforcing sheet of the flexible printed circuit board may be disposed on a partial surface/side surface or the entire surface/side surface of the flexible printed circuit board. The reinforcing sheet is generally made of metal (such as stainless steel, copper, or iron), plastic (such PC, ABS, or PVC), glass epoxy (such as FR4), or other materials. The reinforcing sheet is generally connected to the flexible printed circuit board using an adhesive (such as a thermosetting adhesive or a double-sided adhesive). Because this is common general knowledge to a person skilled in the art, details are not described herein again.

It should be noted herein that the flexible printed circuit board may be of a single layer, two layers, or more than two layers. As shown in FIG. 1k, in the first embodiment, the conductive transmission medium 190 disposed in the portable data cable 100 is a flexible printed circuit board.

A flat band-shaped conductive medium 129 for implementing electrical connection between the first terminal and the second terminal is disposed in the body portion 130. The flat band-shaped conductive medium 129 is a flexible printed circuit board.

A flexible printed circuit board 126 for implementing electrical connection is disposed in the second terminal 120. The flexible printed circuit board 126 includes a frame body 127 matching the shape of the corresponding second terminal 120 and an electrical contact 128 electrically connected to the frame body 127. Although not particularly shown in the drawing, a person of ordinary skill in the art can clearly know that a flexible printed circuit board may also be disposed in the first terminal and that the flexible printed circuit board includes a frame body matching the shape of the corresponding first terminal and an electrical contact electrically connected to the frame body.

In the first embodiment, the flat band-shaped conductive medium 129 is integrally formed with the flexible printed circuit board 126. Similarly, the flexible printed circuit board in the first terminal is also integrally formed with the flat band-shaped conductive medium 129. In other words, in the first embodiment, the flexible printed circuit board 126 disposed in the second terminal 120, the flat band-shaped conductive medium 129, and the flexible printed circuit board disposed in the first terminal 110 are integrally formed to form a single unit. The flexible printed circuit board 126 disposed in the second terminal 120, the flat band-shaped conductive medium 129, and the flexible printed circuit board disposed in the first terminal 110 together form the conductive transmission medium 190.

In the first embodiment, the conductive transmission medium uses a flexible printed circuit board. The reasons why a flexible printed circuit board is used are as follows. The shapes of both the first terminal 110 and the second terminal 120 are relatively complex. If the first terminal 110 and the second terminal 120 are manufactured by injection molding, the conductive transmission medium uses an electronic cable, and the electronic cable is placed in a mold, a mechanism for fixing the electronic cable needs to be added. This would make the mold complex and require manual placement of the electronic cable at a specified position. If the electronic cable is inappropriately fixed, the electronic cable may be crushed during mold clamping, resulting in a poor product. Or if a plastic cement enters a mold cavity during injection and has an extremely large impact force, this will lead to displacement of the electronic cable, resulting in a poor product (for example, the electronic cable is exposed outside a housing). Because the shape of the flexible printed circuit board is flexible and flat, the flexible printed circuit board can be easily placed and fixed in the mold. It should be noted that although the shape of the body portion 130 is simple, problems such as a length offset of the electronic cable, manual placement of the electronic cable, and easy impulse on the electronic cable by a plastic cement occur because the body portion 130 is relatively long, and if an electronic cable is used. The thickness of the flexible printed circuit board is small (usually 0.1 mm to 0.25 mm), and therefore the body portion 130 may also be made to have a small thickness.

As shown in FIG. 1l and FIG. 1m, in the first embodiment, a reinforcing sheet 180 having a shape corresponding to the shape of the frame body 127 is attached on the frame body 127. As shown in FIG. 1m, the reinforcing sheet 180 includes two “l”-shaped reinforcing sheets that are disposed opposite each other in the length direction X. It should be noted that when the conductive transmission medium 190 is a flexible printed circuit board, the flexible printed circuit board is not necessarily provided with a reinforcing sheet, and that the reinforcing sheet needs to be added only in special cases. For example, when the first terminal 110, the second terminal 120, and the body portion 130 are manufactured by an injection process, the flexible printed circuit board is prone to deformation if a plastic cement enters an injection mold from a side surface of the flexible printed circuit board, because the speed of the flowing plastic cement is extremely fast and the plastic cement first gets in contact with the side surface of the flexible printed circuit board. In this case, we may add a reinforcing sheet (such as a stainless steel sheet). Because the hardness of the reinforcing sheet is higher than that of the flexible printed circuit board, the flexible printed circuit board is not prone to deformation after the addition of the reinforcing sheet so that the defect rate is reduced, thereby improving the production efficiency. In addition, the reinforcing sheet may further enhance the strength of the flexible printed circuit board. For example, when an external force is applied in the length or width direction to pull the first terminal or the second terminal, the inside flexible printed circuit board is protected against fracture. When a vulcanized silica gel manufacturing process is used or a plastic cement enters an injection mold from a main surface (a plane perpendicular to the thickness direction) of the flexible printed circuit board, no reinforcing sheet needs to be added. In general, whether to add the reinforcing sheet and the shape and pattern of the reinforcing sheet depend on the process conditions.

The first terminal 110, the second terminal 120, and the body portion 130 are preferably formed by means of injection using materials having flexibility, in particular, plastic materials that are cheap and can be easily obtained (such as TPE, TPU, silica gel, silicon rubber, PC, ABS, and PVC). A housing of the first terminal 110, a housing of the second terminal 120, and the body portion 130 may be integrally formed or may be formed by multiple parts. The body portion 130, for example, may be integrally formed by means of in-mold injection using plastic materials having flexibility.

Next, an exemplary process of wearing the portable data cable 100 (that is, a process of connecting the first terminal 110 and the second terminal 120) is described with reference to FIG. 1f through FIG. 1j.

First, in a first step (as shown in FIG. 1f), the portable data cable 100 is wound so that the second connecting part 121 of the second terminal 120 is opposite the first connecting part 111 of the first terminal 110.

Second, in a second step (as shown in FIG. 1g), the second terminal 120 is raised so that the second terminal 120 is slightly higher than the first terminal 110 in the thickness direction Y.

Next, in a third step (as shown in FIG. 1bh and FIG. 1i), the second connecting part 121 of the second terminal 120 is inclined so that the second connecting part 121 is aligned with the first recess 114.

Then, in a fourth step (as shown in FIG. 1j), an acting force is applied towards the lower left of the drawing along the connection direction X so that the second connecting part 121 enters the first receiving portion 115, and then the first protruding portion 112 and the second protruding portion 122 are separately pressed along the thickness direction Y so that the first protruding portion 112 protrudes upwards along the thickness direction Y into the second recess portion 124, and the second protruding portion 122 protrudes downwards along the thickness direction Y into the first recess portion 114, and the first connecting part 111 enters the second receiving portion 125. Finally, the connected state shown in FIG. 1a through FIG. 1c is entered.

When the first terminal 110 needs to be detached from the second terminal 120, an operation may be performed in the following manner: First, the first protruding portion 112 and the second protruding portion 122 are separately pressed or parts corresponding to the flexible printed circuit board of the first terminal and the second terminal are separately pulled so that the first protruding portion 112 detaches from the second recess portion 124 and the second protruding portion 122 detaches from the first recess portion 114. Then, the second terminal 120 is pulled obliquely upwards in a backward direction along the connection direction X so that the second connecting part 121 is separated from the first receiving portion 115 through the first recess portion 114. Finally, the first terminal 110 is completely separated from the second terminal 120.

According to the first embodiment, in the thickness direction Y, the second connecting part 121 is located in the first receiving portion 115, and the first connecting part Ill is located in the second receiving portion 125. A detachable connection between the first terminal 110 and the second terminal 120 in the connection direction X is implemented using a structure in which a mortise and a tenon are opposite each other and match each other, so as to reduce the thickness of a joint between the first terminal 110 and the second terminal 120 to the greatest extent, thereby providing a light, slim, and good-looking design, and a good user experience.

In addition, by implementing the detachable connection between the first terminal 110 and the second terminal 120 in the connection direction X using the structure in which a mortise and a tenon are opposite each other and match each other, the structure is reliable and does not easily become loose.

### Second Embodiment

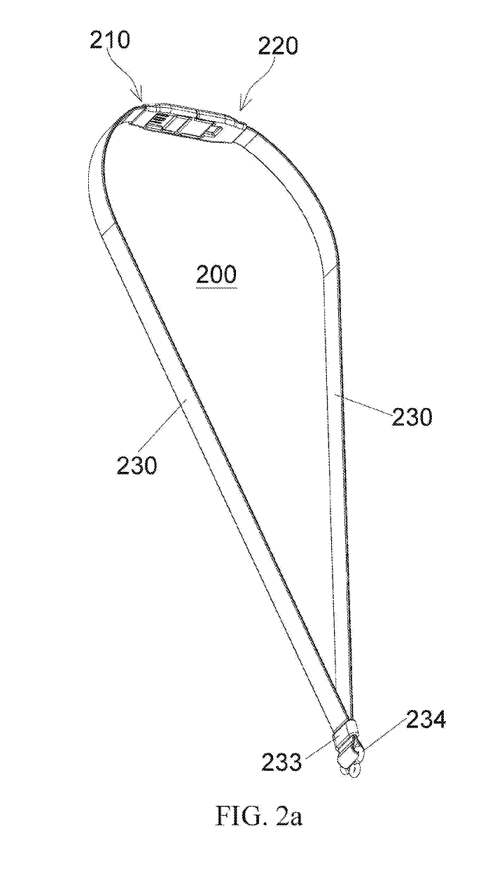

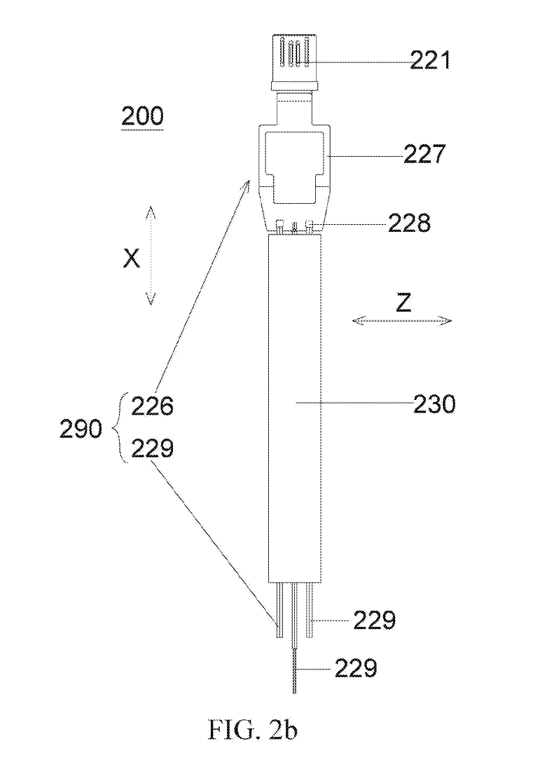

Next, a portable data cable according to a second embodiment of the present invention is described with reference to FIG. 2a and FIG. 2b. In addition, unless otherwise particularly stated, the structure of the portable data cable of the second embodiment is the same as the structure disclosed in the first embodiment and described with reference to FIG. 1a through FIG. 1j. The following mainly describes the aspects of the structure of the portable data cable in the second embodiment that are different from the structure of the first embodiment, and briefly describes the common aspects of the structures.

Unlike the first embodiment, as shown in FIG. 2, the portable data cable 200 in the second embodiment is a name card data cable adapted to be worn on the neck. The portable data cable 200 also includes a first terminal 210, a second terminal 220, and a body portion 230. The structures of the first terminal 210 and the second terminal 220 in this embodiment are the same as those of the first terminal 110 and the second terminal 120 in the first embodiment, and details are not described herein. To facilitate placing a name card, a clip 233 and a connection ring 234 are disposed on the body portion 230. The name card may be connected to the connection ring 234 or may be connected using another component (such as a nylon rope or a key ring). The clip 233 may limit the position of the connection ring 234. The foregoing name card may alternatively be a common wearable product for daily use such as a mobile phone, a mobile phone cover, or a key.

Unlike the first embodiment, in the second embodiment, a conductive transmission medium 290 disposed in the first terminal, the second terminal, and the body portion is a combination of an electronic cable and a flexible printed circuit board.

A connection medium 229 for implementing electrical connection between the first terminal and the second terminal is disposed in the body portion. The connection medium 229 is an electronic cable.

A flexible printed circuit board 226 for implementing electrical connection is disposed in the second terminal. The flexible printed circuit board 226 includes a frame body 227 matching the shape of the corresponding second terminal and an electrical contact 228 electrically connected to the frame body 227. Although not particularly shown in the drawing, a flexible printed circuit board for implementing electrical connection may also be disposed in the first terminal, and the flexible printed circuit board includes a frame body matching the shape of the corresponding first terminal and an electrical contact electrically connected to the frame body.

Unlike the first embodiment, in the second embodiment, the first terminal 210, the second terminal 220, and the body portion 230 are designed and manufactured independently and are not formed by integral injection. The conductive transmission medium disposed in the first terminal, the second terminal, and the body portion is a combination of an electronic cable and a flexible printed circuit board.

In this embodiment, the conductive transmission medium disposed in the first terminal, the second terminal, and the body portion is a combination of an electronic cable and a flexible printed circuit board. The reasons are that the conductive transmission medium part, that is, the connection medium 229, in the body portion 130 needs to be long (usually approximately 1 meter, and the actual length varies from person to person) enough to be worn on the neck, and that the cost of a long flexible printed circuit board is excessively high, which is several times or even ten times higher than the cost of the electronic cable. The conductive transmission medium part in the first terminal and the second terminal uses a flexible printed circuit board. Compared with the case in which an electronic cable is used, in an injection molding process, the flexible printed circuit board is easy to fix and is not easily displaced, thus improving the production efficiency and yield. The body portion 230 is a covering layer of the electronic cable and is generally formed by injection molding using an extruder and/or is generally formed by weaving and winding using a braider. Because this is common general knowledge to a person skilled in the art, details are not described herein again.

In addition, the portable data cable is not limited to a bracelet and a name card data cable. For example, the portable data cable may alternatively be jewelry such as a necklace.

### Third Embodiment

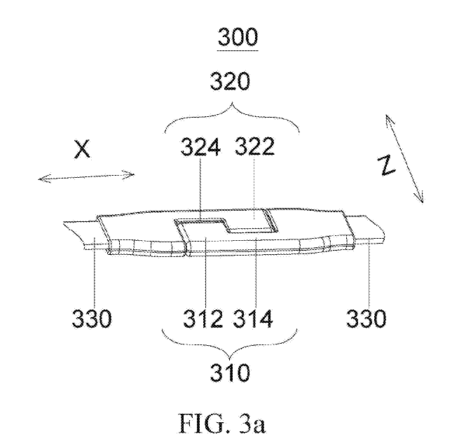

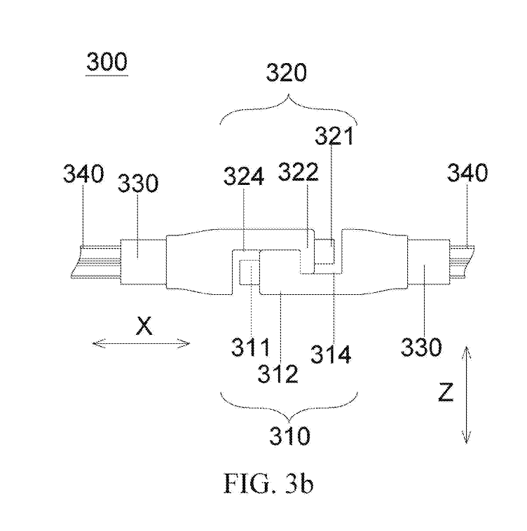

Next, a portable data cable according to the third embodiment of the present invention is described with reference to FIG. 3a and FIG. 3b. In addition, unless otherwise particularly stated herein, the structure of the portable data cable according to the third embodiment is the same as the structure disclosed in the first embodiment and described with reference to FIG. 1a through FIG. 1j. The following mainly describes the aspects of the structure of the third embodiment that are different from the structure of the portable data cable of the first embodiment, and briefly describes the common aspects of these two structures.

As shown in FIG. 3a and FIG. 3b, a portable data cable 300 of this embodiment includes a first terminal 310, a second terminal 320, and a body portion 330 connected between the first terminal 310 and the second terminal 320. The first terminal 310 and the second terminal 320 are respectively located on two ends of the portable data cable 300.

In the third embodiment, a conductive transmission medium 340 hidden in the first terminal 310, the second terminal 320, and the body portion 330 is an electronic cable. In other words, the conductive transmission medium in the first terminal 310 is an electronic cable, the conductive transmission medium in the second terminal 320 is also an electronic cable, and the conductive transmission medium in the body portion 330 is also an electronic cable. Each of the multiple electronic cables of the conductive transmission medium 340 hidden in the first terminal 310, the second terminal 320, and the body portion 330 is integral. The first terminal 310 includes a first interface 311, a first protruding portion 312, a first recess portion 314, and a first receiving portion (not shown), all of which are sequentially disposed along a connection direction X.

The second terminal 320 includes a second interface 321, a second protruding portion 322, a second recess portion 324, and a second receiving portion (not shown), all of which are sequentially disposed along the connection direction X.

Unlike the first embodiment, in the portable data cable 300 of the third embodiment shown in FIG. 3a and FIG. 3b, the first protruding portion 312 and the second protruding portion 322 separately protrude towards opposite directions along a width direction Z. Correspondingly, the first recess portion 314 and the second recess portion 324 are separately recessed towards opposite directions along the width direction Z. In other words, as shown in FIG. 3b, when the first terminal 310 is connected to the second terminal 320, the first protruding portion 312 protrudes leftwards (the upper part of the drawing) along the width direction Z into the second recess portion 324, and the second protruding portion 322 protrudes rightwards (the lower part of the drawing) along the width direction Z into the first recess portion 314. In a thickness direction perpendicular to the connection direction X and the width direction Z, the first recess portion 314 and the second recess portion 324 are through holes that extend downwards.

Unlike the first embodiment, in the portable data cable 300 of the third embodiment, the first receiving portion and the second receiving portion are closed towards both an inner side and an outer side along the thickness direction. The first receiving portion is opened only on a side close to the first recess portion 314 to accommodate the second interface 321. The second receiving portion is opened only on a side close to the second recess portion 324 to accommodate the first interface 311. With this structure, the first interface 311 and the second interface 321 do not detach easily by mistake, making the connection between the first terminal 310 and the second terminal 320 can be more reliable.

It should be noted that in this embodiment, the first terminal 310 is completely identical to the second terminal 320. Certainly, a person of ordinary skill in the art should know that the first terminal 310 may not be completely identical to the second terminal 320. For example, the first interface 311 is not identical to the second interface 321, or the forms of the conductive transmission media in the first terminal 310 and the second terminal 320 are not identical.

### Fourth Embodiment

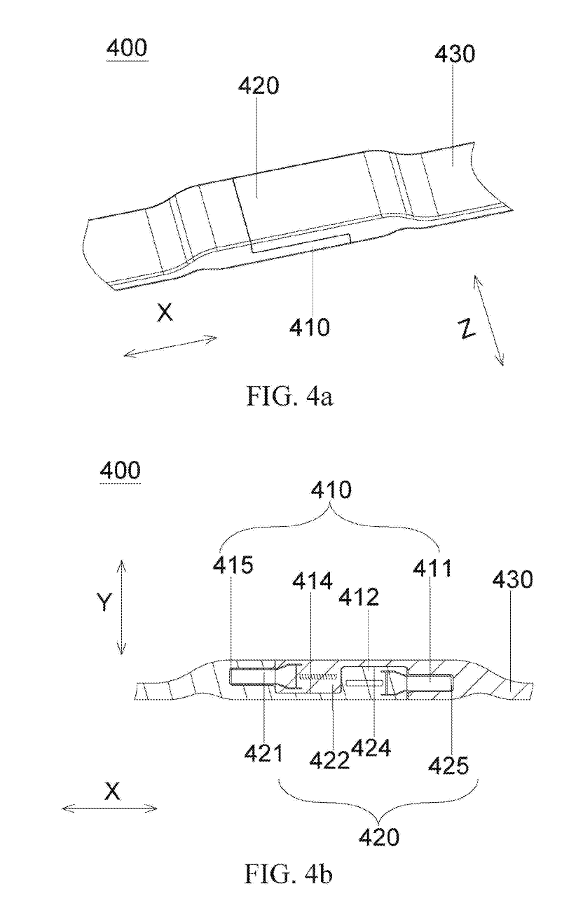

A portable data cable according to a fourth embodiment of the present invention is described with reference to FIG. 4a and FIG. 4b. Unless otherwise particularly stated herein, the structure of the portable data cable according to the fourth embodiment is the same as the structure disclosed in the first embodiment and described with reference to FIG. 1a through FIG. 1j. The following mainly describes the aspects of the structure of the portable data cable of the fourth embodiments that are different from the structure of the first embodiment, and briefly describes the common aspects of these two structures.

As shown in FIG. 4a and FIG. 4b, a portable data cable 400 of this embodiment includes a first terminal 410, a second terminal 420, and a body portion 430 connected between the first terminal 410 and the second terminal 420. The first terminal 410 and the second terminal 420 are respectively located on two ends of the portable data cable 400.

As shown in FIG. 4b, the first terminal 410 includes a first interface 411, a first protruding portion 412, a first recess portion 414, and a first receiving portion 415, all of which are sequentially disposed from the right side to the left side of the drawing along a connection direction X.

As shown in FIG. 4b, the second terminal 420 includes a second interface 421, a second protruding portion 422, a second recess portion 424, and a second receiving portion 425, all of which are sequentially disposed from the left side to the right side of the drawing along the connection direction X.

Unlike the first embodiment, as shown in FIG. 4a and FIG. 4b, in the portable data cable 400 of the fourth embodiment, the first receiving portion 415 and the second receiving portion 425 are closed towards both an inner side and towards an outer side along a thickness direction. In addition, when the first terminal 410 is connected to the second terminal 420, the first recess portion 414 is a bottom-containing groove recessed downwards along the thickness direction Y, the second recess portion 424 is a bottom-containing groove recessed upwards along the thickness direction Y, the first protruding portion 412 protrudes upwards along the thickness direction Y into the second recess portion 424, and the second protruding portion 422 protrudes downwards along the thickness direction Y into the first recess portion 414.

In this embodiment, the first recess portion 414 and the second recess portion 424 are bottom-containing grooves. The first terminal 110 and the second terminal 120 have enough tension strength. No transition portion is disposed between the first protruding portion 412 and the first recess portion 414 nor between the second protruding portion 422 and the second recess portion 424, so that the structure is more esthetic and compact.

### Fifth Embodiment

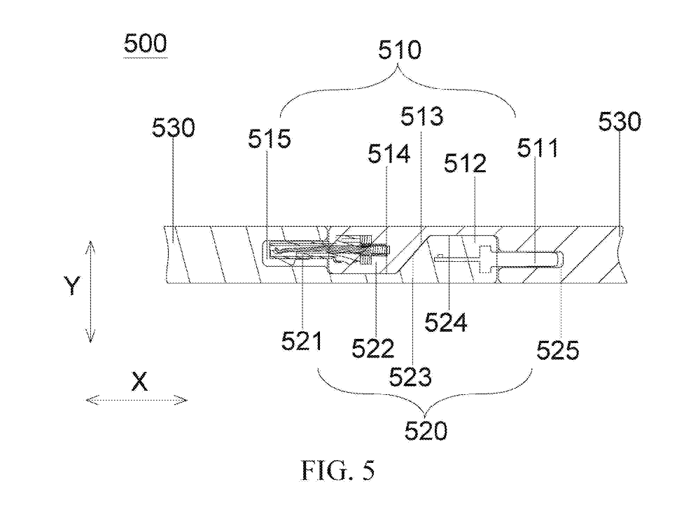

Next, a portable data cable involved in a fifth embodiment of the present invention is described with reference to FIG. 5. Unless otherwise particularly stated herein, the structure of the portable data cable involved in the fifth embodiment is the same as the structure disclosed in the fourth embodiment and described with reference to FIG. 4a and FIG. 4b. The following mainly describes the aspects of the structure of the fifth embodiment that are different from the structure of the portable data cable of the fourth embodiment, and briefly describes the common aspects of these two structures.

As shown in FIG. 5, a portable data cable 500 of this embodiment includes a first terminal 510, a second terminal 520, and a body portion 530 connected between the first terminal 510 and the second terminal 520. The first terminal 510 and the second terminal 520 are respectively located on two ends of the portable data cable 500.

As shown in FIG. 5, the first terminal 510 includes a first interface 511, a first protruding portion 512, a first recess portion 514, and a first receiving portion 515, all of which are sequentially disposed from the right side to the left side of the drawing along a connection direction X.

As shown in FIG. 5, the second terminal 520 includes a second interface 521, a second protruding portion 522, a second recess portion 524, and a second receiving portion 525, all of which are sequentially disposed from the left side to the right side of the drawing along the connection direction X.

As shown in FIG. 5, unlike the fourth embodiment, in the portable data cable of the fifth embodiment, a first transition inclined surface 513 is disposed between the first protruding portion 512 and the first recess portion 514, and a second transition inclined surface 523 is disposed between the second protruding portion 522 and the second recess portion 524. When the first terminal 510 is connected to the second terminal 520, the first transition inclined surface 513 matches the second transition inclined surface 523.

Comparing to the fourth embodiment above, in the fifth embodiment, in a process of establishing connection between the first terminal 510 and the second terminal 520, the first transition inclined surface 513 and the second transition inclined surface 523 may better facilitate insertion of the second interface 521 into the first receiving portion 515, and insertion of the first interface 511 into the second receiving portion 525, and the operation is smoother.

In the description of the present invention, the terms “first” and “second” are used for the purpose of description only and should not be construed as indicating or implying the relative importance of elements or specifying the number of the indicated features. Therefore, features defined with “first” and “second” may explicitly or implicitly include one or more of the features. In the description of the embodiments of the present invention, the term “multiple” means two or more unless otherwise specifically and expressly defined herein.

In the description of the present invention, it should be noted that unless otherwise expressly stipulated and defined herein, the terms “connected” and “connection” should be construed broadly. For example, the connection may be a fixed connection, a detachable connection, or an integral connection; the connection may be a mechanical connection, or an electrical connection; and the connection may be a direct connection, or an indirect connection via a medium. A person of ordinary skill in the art can understand specific meanings of the foregoing terms in the present invention according to specific cases. In addition, in the description of the present invention, under otherwise stated, the term “multiple” means two or more.

Although the embodiments of the present invention are shown and described herein, a person of ordinary skill in the art can make various changes, modifications, substitutions, and variations to these embodiments without departing from the principle and objective of the present invention; the scope of the present disclosure is defined by the claims and their equivalents.

What is claimed is:

1. A portable data cable, comprising a first terminal and a second terminal that are disposed on two ends of the portable data cable, and a body portion connected between the first terminal and the second terminal, wherein:
the first terminal comprises a first interface, a first protruding portion, a first recess portion, and a first receiving portion, all of which are sequentially disposed along a connection direction;
the second terminal comprises a second interface, a second protruding portion, a second recess portion, and a second receiving portion, all of which are sequentially disposed along the connection direction,
wherein the first recess portion is configured to facilitate insertion of the second interface into the first receiving portion, and the second recess portion is configured to facilitate insertion of the first interface into the second receiving portion, and
wherein the first terminal and the second terminal are configured to be capable of being connected by using mortise-and-tenon structures and making the portable data cable become a closed loop, whereby the first interface is accommodated in the second receiving portion, and the second interface is accommodated in the first receiving portion.

2. The portable data cable according to claim 1, wherein when the first terminal is connected to the second terminal, the first protruding portion and the second recess portion match each other in a mortise-and-tenon manner in a first matching direction, and the second protruding portion and the first recess portion match each other in a mortise-and-tenon manner in a second matching direction opposite the first matching direction.

3. The portable data cable according to claim 2, wherein the first recess portion and the second recess portion are both through holes that extend vertically along a thickness direction.

4. The portable data cable according to claim 3, wherein the first receiving portion and the second receiving portion are open towards an inner side along the thickness direction and are closed towards an outer side.

5. The portable data cable according to claim 4, wherein when the first terminal is connected to the second terminal, the first protruding portion protrudes upwards along the thickness direction into the second recess portion and the second protruding portion protrudes downwards along the thickness direction into the first recess portion.

6. The portable data cable according to claim 1, wherein a first transition portion is disposed between the first protruding portion and the first recess portion, a second transition portion is disposed between the second protruding portion and the second recess portion, and when the first terminal is connected to the second terminal, the first transition portion vertically overlaps with the second transition portion.

7. The portable data cable according to claim 1, wherein when the first terminal is connected to the second terminal, the first protruding portion protrudes leftwards along a width direction into the second recess portion, and the second protruding portion protrudes rightwards along the width direction into the first recess portion.

8. The portable data cable according to claim 1, wherein the first receiving portion and the second receiving portion are closed towards both an inner side and an outer side along the thickness direction.

9. The portable data cable according to claim 2, wherein the first receiving portion and the second receiving portion are closed towards both an inner side and an outer side along the thickness direction, and when the first terminal is connected to the second terminal, the first recess portion is a bottom-containing groove recessed downwards along the thickness direction, the second recess portion is a bottom-containing groove recessed upwards along the thickness direction, the first protruding portion protrudes upwards along the thickness direction into the second recess portion, and the second protruding portion protrudes downwards along the thickness direction into the first recess portion.

10. The portable data cable according to claim 1, wherein a first transition inclined surface is disposed between the first protruding portion and the first recess portion, a second transition inclined surface is disposed between the second protruding portion and the second recess portion, and when the first terminal is connected to the second terminal, the first transition inclined surface matches the second transition inclined surface.

11. The portable data cable according to claim 1, wherein a flexible printed circuit board implementing electrical connection is disposed within the first terminal and/or the second terminal, the flexible printed circuit board comprising a frame body and an electrical contact electrically connected to the frame body, the frame body matching the shape of corresponding first terminal or second terminal.

12. The portable data cable according to claim 11, wherein a flexible printed circuit board implementing electrical connection is disposed within both of the first terminal and the second terminal, and a connection medium located between the flexible printed circuit board on the first terminal and the flexible printed circuit board on the second terminal is a flat band-shaped conductive medium.

13. The portable data cable according to claim 11, wherein a reinforcing sheet having a shape corresponding to the shape of the frame body is attached on the frame body.

14. A portable data cable, comprising a first terminal and a second terminal that are disposed on two ends of the portable data cable, and a body portion connected between the first terminal and the second terminal, wherein:
the first terminal comprises a first interface, a first protruding portion, a first recess portion, and a first receiving portion, all of which are sequentially disposed along a connection direction:
the second terminal comprises a second interface, a second protruding portion, a second recess portion, and a second receiving portion, all of which are sequentially disposed along the connection direction,
wherein the first recess portion is configured to facilitate insertion of the second interface into the first receiving portion, and the second recess portion is configured to facilitate insertion of the first interface into the second receiving portion,
wherein the first terminal and the second terminal are configured to be capable of being connected by using mortise-and-tenon structures and making the portable data cable become a closed loop, whereby the first interface is accommodated in the second receiving portion, and the second interface is accommodated in the first receiving portion,
wherein when the first terminal is connected to the second terminal, the first protruding portion and the second recess portion match each other in a mortise-and-tenon manner in a first matching direction, and the second protruding portion and the first recess portion match each other in a mortise-and-tenon manner in a second matching direction opposite the first matching direction,
wherein the first recess portion and the second recess portion are both through holes that extend vertically along a thickness direction,
wherein the first receiving portion and the second receiving portion are open towards an inner side along the thickness direction and are closed towards an outer side,
wherein when the first terminal is connected to the second terminal, the first protruding portion protrudes upwards along the thickness direction into the second recess portion and the second protruding portion protrudes downwards along the thickness direction into the first recess portion, and
wherein a first transition portion is disposed between the first protruding portion and the first recess portion, a second transition portion is disposed between the second protruding portion and the second recess portion, and when the first terminal is connected to the second terminal, the first transition portion vertically overlaps with the second transition portion.

15. A portable data cable, comprising a first terminal and a second terminal that are disposed on two ends of the portable data cable, and a body portion connected between the first terminal and the second terminal, wherein:
the first terminal comprises a first interface, a first protruding portion, a first recess portion, and a first receiving portion, all of which are sequentially disposed along a connection direction;
the second terminal comprises a second interface, a second protruding portion, a second recess portion, and a second receiving portion, all of which are sequentially disposed along the connection direction,
wherein the first recess portion is configured to facilitate insertion of the second interface into the first receiving portion, and the second recess portion is configured to facilitate insertion of the first interface into the second receiving portion, and
wherein the first terminal and the second terminal are configured to be capable of being connected by using mortise-and-tenon structures and making the portable data cable become a closed loop, whereby the first interface is accommodated in the second receiving portion, and the second interface is accommodated in the first receiving portion,
wherein when the first terminal is connected to the second terminal, the first protruding portion and the second recess portion match each other in a mortise-and-tenon manner in a first matching direction, and the second protruding portion and the first recess portion match each other in a mortise-and-tenon manner in a second matching direction opposite the first matching direction,
wherein the first recess portion and the second recess portion are both through holes that extend vertically along a thickness direction,
wherein when the first terminal is connected to the second terminal, the first protruding portion protrudes leftwards along a width direction into the second recess portion, and the second protruding portion protrudes rightwards along the width direction into the first recess portion, and
wherein the first receiving portion and the second receiving portion are closed towards both an inner side and an outer side along the thickness direction.
